(19) United States
(12) Patent Application Publication
(10) Pub. No.: US 2021/0328126 A1
(43) Pub. Date: Oct. 21, 2021

(54) OPTICAL DETECTION APPARATUS AND METHOD

(71) Applicant: Nokia Technologies Oy, Espoo (FI)

(72) Inventor: David BITAULD, Cambridge (GB)

(21) Appl. No.: 16/332,650

(22) PCT Filed: Sep. 14, 2016
(86) PCT No.: PCT/FI2016/050635

§ 371 Date: Mar. 12, 2019

(51) Int. Cl. H01L 39/10; H01L 39/14; G01J 5/02

(52) U.S. Cl. CPC H01L 39/10; B82Y 15/00; G01J 5/023; H01L 39/14

(57) ABSTRACT

According to an example aspect of the present invention, there is provided an apparatus comprising: an optic fibre input (31); a plurality of photonic detectors (34) comprising a nanowire and biased with an electric input; a set of modulators (35) connected to the optic fibre input (31), each of the modulators (35) being connected to one of the photonic detectors (34) for forming a modulated optical detector signal; and an optic fibre output (40) for the modulated optical detector signal. The optic fibre input (31), the photonic detectors (34), the set of modulators (35), and the optic fibre output (40) are formed on a single chip (1).

### FIELD

The present invention relates to optical detecting apparatuses and methods, and more particularly to reading multiple photonic detectors.

### BACKGROUND

In general, photon detectors convert photons into readable electrical signals, and are used in a variety of detectors and sensors in communications and computing systems, astronomy, and other fields. There are many applications, in which information is encoded and transmitted in a signal made up of photons. The use of nanowires in photon detectors has been under research. In many nanowire-based detectors, one or more nanowires are positioned on a substrate toward which photons are directed. Individual photons can couple with the nanowire(s) upon contact, producing a detectable signal.

Superconducting nanowire single photon detectors (SNSPDs) use low-temperature nanowires covering a small area on a substrate. By current-biasing the nanowires close to their superconducting critical current, they become very sensitive to the absorbed energy of individual photons. Even a single incident photon which is absorbed in the nanowire temporarily creates a region of non-superconductance in the otherwise superconducting wire. Such hot spot momentarily alters the electrical properties of the nanowire, until the nanowire resets itself to become superconducting again. Due to their very good speed and signal-to-noise ratio properties, SNSPDs are very attractive for many applications despite the need for refrigeration. For example, such applications include quantum computing, infrared photoemission imaging, Laser-Induced Detection and Ranging (LIDAR), on-chip quantum optics, single plasmon detection, quantum plasmonics, single electron detection, single a and R particles detection, oxygen single luminescence detection and ultra-long distance classical communication.

Recent developments of the technology prove that many detectors can be fabricated on the same silicon chip, thus dramatically reducing the cost of refrigeration per detector. Usually electrical biasing and readout of the SNSPDs is done by connecting them with metallic probes or metallic coaxial cable. However, there are substantial limitations in terms of space and heat conduction for implementing multiple detectors on a chip when using metallic cables for readout.

### SUMMARY

The invention is defined by the features of the independent claims. Some specific embodiments are defined in the dependent claims.

According to a first aspect, there is provided an apparatus, comprising: an optic fibre input; a plurality of photonic detectors comprising a nanowire and biased with an electric input; a set of modulators connected to the optic fibre input, each of the modulators being connected to one of the photonic detectors for forming a modulated optical detector signal; and an optic fibre output for the modulated optical detector signal. The optic fibre input, the photonic detectors, the set of modulators, and the optic fibre output are formed on a single chip.

According to a second aspect, there is provided a method, comprising: receiving light by an optic fibre input on a chip;
generating detection output by a plurality of photonic detectors on the chip comprising a nanowire and biased with an electric input;
generating a modulated optical detector signal by a set of modulators on the chip connected to the photonic detectors on the basis of the detection output from the photonic detectors and the received light; and
providing the modulated optical detector signal to an optic fibre output of the chip.

According to an embodiment, the chip further comprises a first demultiplexer connected to the set of modulators for providing a selected wavelength of light from a multi-wavelength light source to each modulator.

According to an embodiment, the chip further comprises a multiplexer for combining signals from each of the modulators into a single optic fibre connectable to the chip.

According to an embodiment, the apparatus further comprises or is connectable to:
a second demultiplexer for demultiplexing the modulated optical detector signal in the single optic fibre, and
a set of interferometric phase detectors connected to the second multiplexer, arranged to detect modulation at the demultiplexed optical detector signal.

According to an embodiment, biasing of the plurality of photonic detectors is arranged with a single electric wire.

### BRIEF DESCRIPTION OF THE DRAWINGS

FIG. 1 illustrates a chip unit with elements in accordance with at least some embodiments of the present invention;

FIGS. 2a and 2b illustrate an example apparatus capable of supporting at least some embodiments of the present invention;

FIGS. 3 and 4 illustrate examples of photonic chips in accordance with at least some embodiments of the present invention;

FIG. 5 illustrates an example electrical circuit for an apparatus capable of supporting at least some embodiments of the present invention;

FIG. 6 illustrates an example photonic detector for an apparatus capable of supporting at least some embodiments of the present invention;

FIG. 7 illustrates an example electrical circuit for an apparatus capable of supporting at least some embodiments of the present invention;

FIGS. 8a and 8b illustrate modulator arrangements in accordance with at least some embodiments of the present invention;

FIG. 9 illustrates an example electrical circuit for an apparatus capable of supporting at least some embodiments of the present invention;

FIGS. 10a and 10b illustrate examples of interferometric phase shift detectors capable of supporting at least some embodiments of the present invention;

FIG. 11 illustrates an example of interferometric phase shift detector with reference signal capable of supporting at least some embodiments of the present invention; and

FIG. 12 illustrates a method in accordance with at least some embodiments of the present invention.

### EMBODIMENTS

Simultaneous readout of a large number of detectors with individual metallic cables is difficult or even impossible both in terms of space and heat conduction from outside the cryostat to the detector chip. However, optic fibers have, by far, a higher bandwidth as well as lower thermal conductivity than metallic coaxial cable. A cryogenically refrigerated photonic chip capable of hosting a plurality of optical detectors, such as SNSPDs, and optical modulators is now provided to receive and detect single photons, and output a modulated optical signal. This enables to implement much more optical detectors on a single chip than by using metallic wires for readout. For example, hundreds of detectors may be readout from a single chip in a cryostat.

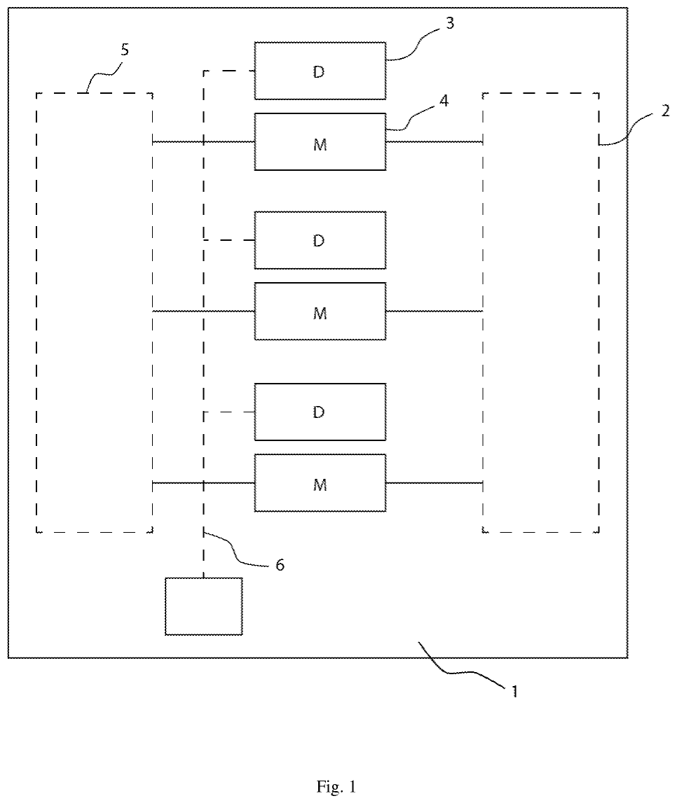

As illustrated in FIG. 1, a chip 1 according to some embodiments comprises an optic fibre input 2, a plurality of photonic detectors 3 comprising at least one nanowire, and a set of modulators 4 connected to the optic fibre input. The chip 1 may cryogenically refrigerated by a cryostat. Each of the electro-optical modulators 4 is connected to one of the photonic detectors and generates photonic detection output indicating photon detections to the modulator. Based on the detection output and the received light, the modulators 4 generate a modulated optical detector signal.

The modulated optical detector signal is provided to an optic fibre output 5 for further transmission. The photonic detectors are biased with electric input 6. Since these elements are integrated in the same unit, one or more further RF transmission lines with given impedances from the chip may be avoided. For example, since the detectors may now be directly connected to the modulators at the single chip, further impedance matching components may be avoided.

A single optic fibre may be connected to the input 2 and/or the output 5. The chip 1 and further the input 2 may further comprise a demultiplexer connected to the set of modulators to provide input light for each of the modulators 4. The chip 1 and further the output 5 may further comprise a multiplexer for combining signals from each of the modulators for output to a single optic fibre connectable to the chip.

In order to be able to readout multiple detectors with a single fibre input and output a wavelength multiplexing may be used. Thus, the multiplexer may be a wavelength multiplexer, such as an arrayed waveguide (AWG), for providing a selected wavelength of light from a multi-wavelength light source to each modulator. AWGs fabricated on silicon platform capable of separating hundreds of wavelengths have been proposed [1].

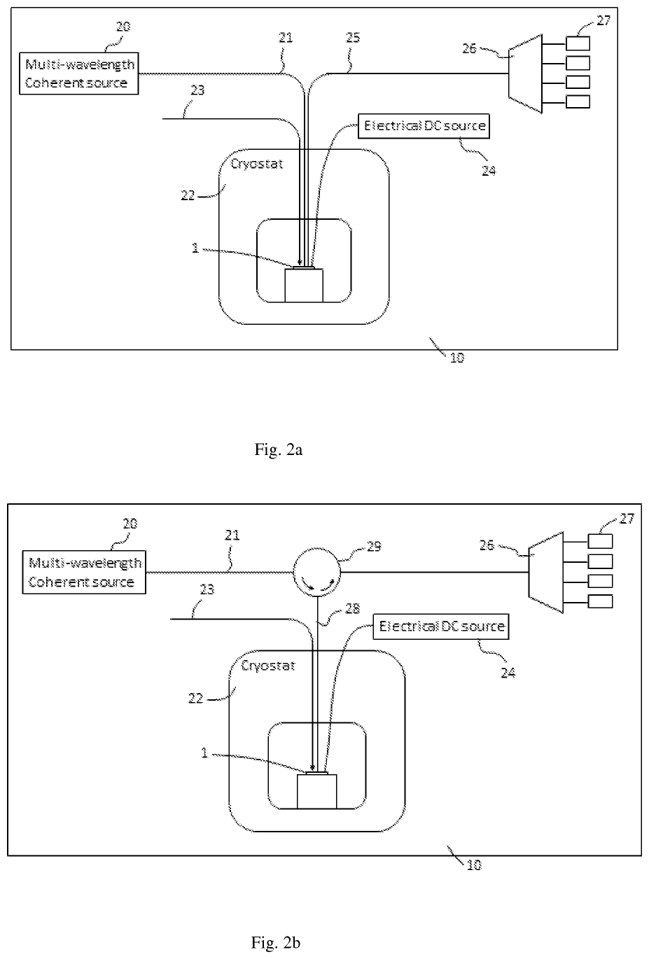

FIGS. 2a and 2b illustrate example systems or apparatuses 10 comprising the chip 1 and further elements, capable of supporting at least some embodiments, and illustrate electrical and optical external setup when applying wavelength multiplexing. The chip 1 is cryogenically refrigerated chip in a cryostat 22.

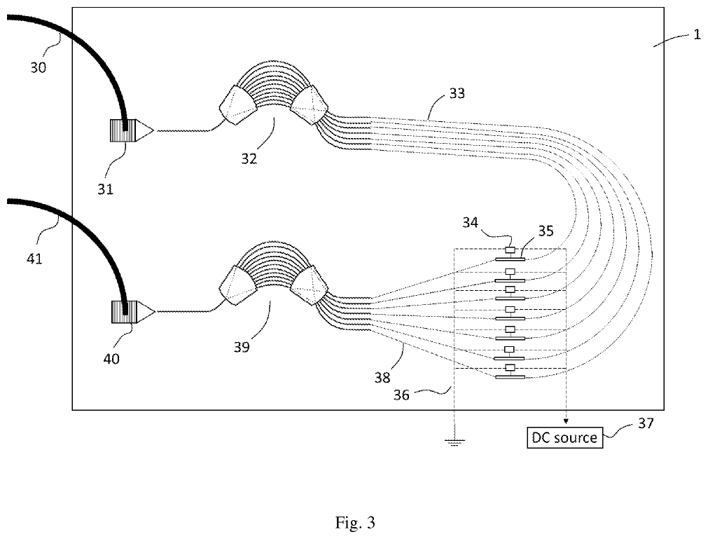

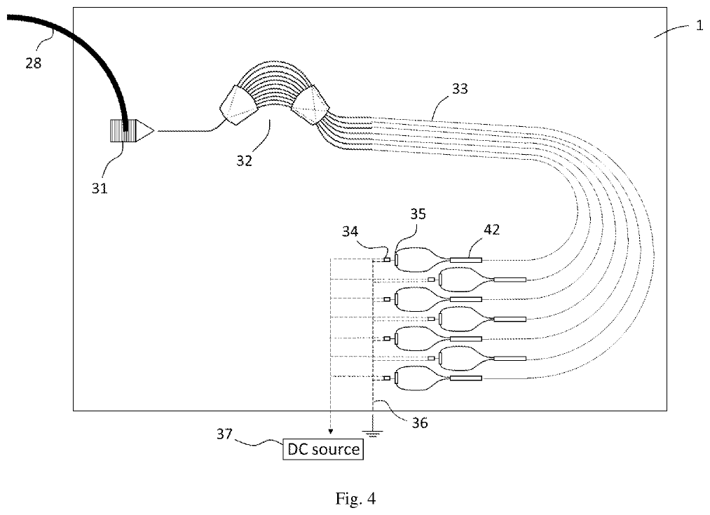

A multiple wavelength laser source 20, or a set of multiplexed lasers, injects light into an optic input fibre 21 that will guide the light into the cryostat 22 and to the chip 1. For example, multiple wavelength laser sources already available or proposed for Dense Wavelength Division Multiplexing (DWDM) communications may be applied. A single photon input 23 is provided to the chip 1 and further to the detectors on the chip. The single photon input 23 may be fed through an optic fibre or an optical window, for example. An electrical direct current (DC) source 24 is connected to the chip 1 to bias the detectors. The light is de-multiplexed on the chip, further examples being illustrated below in connection with FIGS. 3 and 4, modulated on the basis of detection output from the detectors 3 indicating photon detections, and re-multiplexed before being injected in an output fibre 25. Outside the cryostat, the light is de-multiplexed again by the demultiplexer 26 and the modulation may be measured with interferometric phase detectors 27.

As illustrated in the example of FIG. 2b, a single fibre 28 can be used both to input non-modulated light and output modulated light. The input light and output light can be separated with a circulator 29.

FIG. 3 illustrates how the photonic chip 1 may be arranged to de-multiplex, modulate and re-multiplex the light. The incoming light from input fibre 30, such as the fibre 21 of the apparatus 10 illustrated in FIG. 2a, may be coupled by a coupler 31 to a demultiplexer 32. For example, the light may be coupled vertically with a grating coupler or horizontally with a tapered waveguide or inverse taper waveguide. A detector 34 may be directly connected to each modulator 35.

A single DC metallic cable 36 coupled towards DC source 37 can be used to bias the detectors 34. The light is wavelength de-multiplexed for example by an AWG. Each of the channels 33 from the demultiplexer goes through a modulator 35 driven by the detector output, such as a phase shifter or amplitude modulator. After the modulation, the channels 38 are fed into a multiplexer 39, such as an AWG, and coupled via a coupler 40 into the output fibre 41, such as the fibre 25.

In case a single fibre 28 is used for input and output, the configuration shown in FIG. 4 can be used. Light from the single fibre 28 is coupled via a coupler 31 to the de-multiplexer 32. After de-multiplexing 32, each channel 33 may be split by a 1×2 splitter 42 in two channels that loop back into each other. Given that the optical path of the light travelling in both directions of the loop is the same, they will interfere constructively when combined again in the reverse direction. The modulation can be performed by the modulator 35 along this loop, as in FIG. 4, or before the splitter. On the latter case, the loop can be replaced by a reflector.

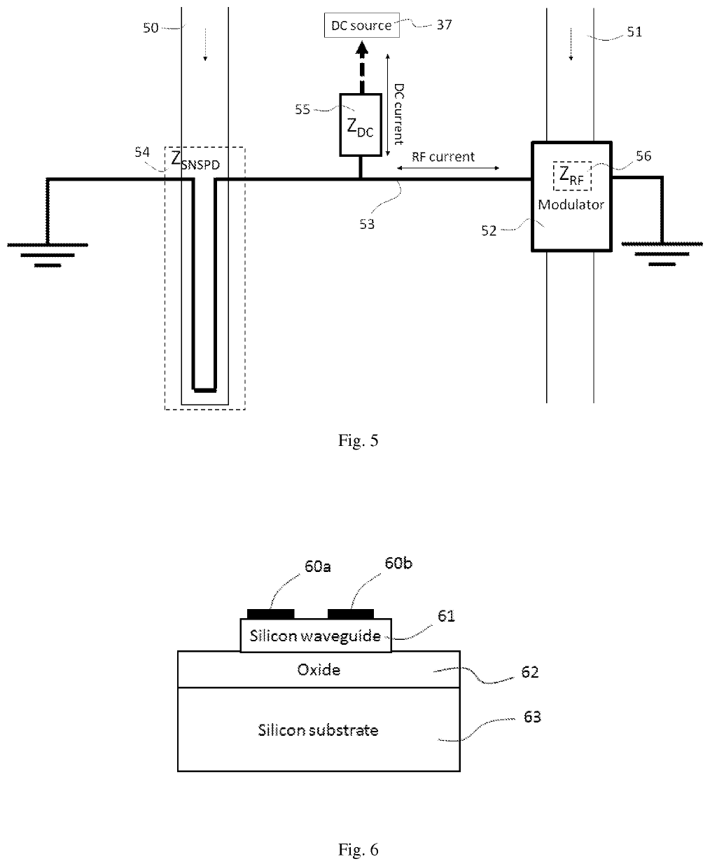

With reference to FIG. 5, in some embodiments the detectors, such as SNSPDs, are deposited on a photon waveguide 50 in which the single photons to be detected are injected. The modulator 52 may be arranged on a readout waveguide 51. The light can be coupled from an optic fibre with the help of a grating coupler or a taper. However, there may be also other methods for submitting the photons on the waveguide, such as application of lensed fibre.

FIG. 6 illustrates cross-section of a photon waveguide detector according to an embodiment, such as the photon waveguide 50 of FIG. 5. Silicon waveguide 61 is provided on top of oxide 62 layer on top of silicon substrate 63. Super-conducting nanowires 60a and 60b are provided on top of the silicon waveguide 61.

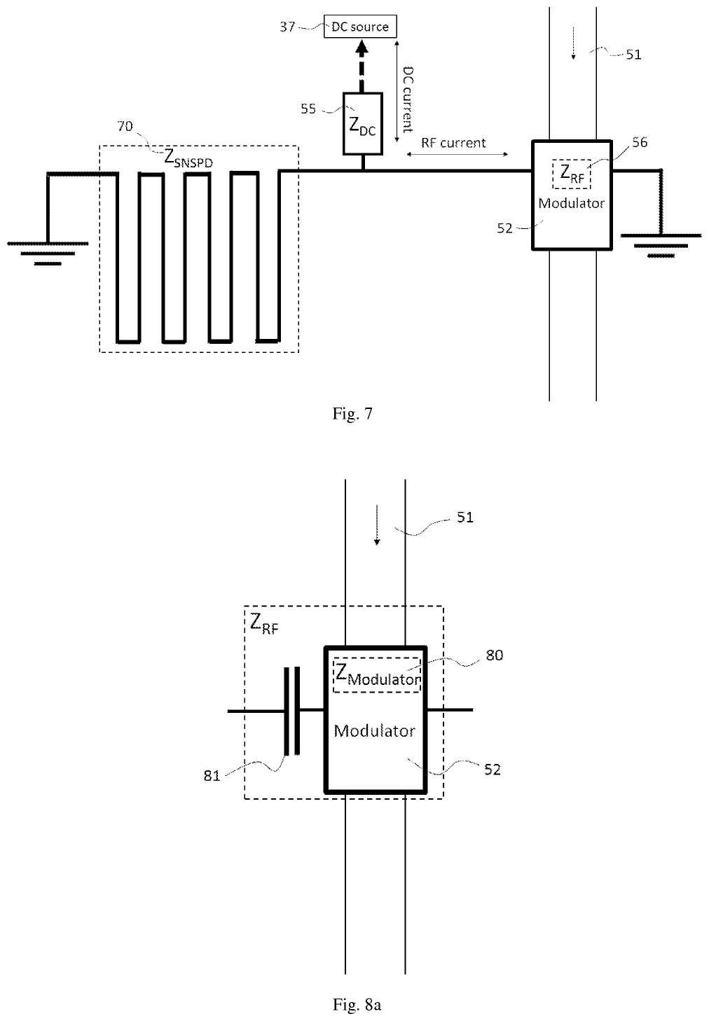

In another embodiment illustrated in FIG. 7, the detector is a vertically coupled SNSPD. The light can be coupled directly from a fibre or from an optical window in the cryostat.

FIGS. 5 and 7 further illustrate the on-chip electrical connection between the SNSPD and the modulator. A DC connection from a DC source 37 is used to bias the SNSPD, while the RF response 53 of the SNSPD as the optical detection output will be transferred to the modulator 52.

In order to have optimum modulation, the impedances in the three branches, i.e. Z_{SNSPD} 54, 70, Z_{DC} 55, Z_{RF} 56, are arranged as follows: only DC and low frequency current runs through Z_{DC}. Only high frequency current runs through Z_{RF}. Both DC and RF current can run in the SNSPD branch. It is to be noted that in conventional electrical readout of SNSPDs a bias tee is instead typically used to implement the above conditions. Z_{RF} 56 needs to be higher than Z_{DC} 55 at low frequency and lower than Z_{DC} 55 at high frequency. This is automatically the case if the modulator is capacitive (Z_{RF}˜1/jωC). Then Z_{DC} could be simply a resistor, for example 50 ohms, and the modulator's impedance would be naturally higher at low frequency and lower at high frequency.

The modulator 4, 35, 52 may be a silicon modulator or an indium phosphide modulator, for example. A silicon modulator may be based on MOS capacitor, an example of such modulator being provided in IEEE publication [2] “Silicon Photonic Modulator Based on a MOS-Capacitor and a CMOS Driver”, M. Webster et al, 19-22 Oct. 2014, ISSN 1550-8781, DOI 10.1109/CSICS.2014.6978577, http://ieeexplore.org/stamp/stamp.jsp?arnumber=6978577.

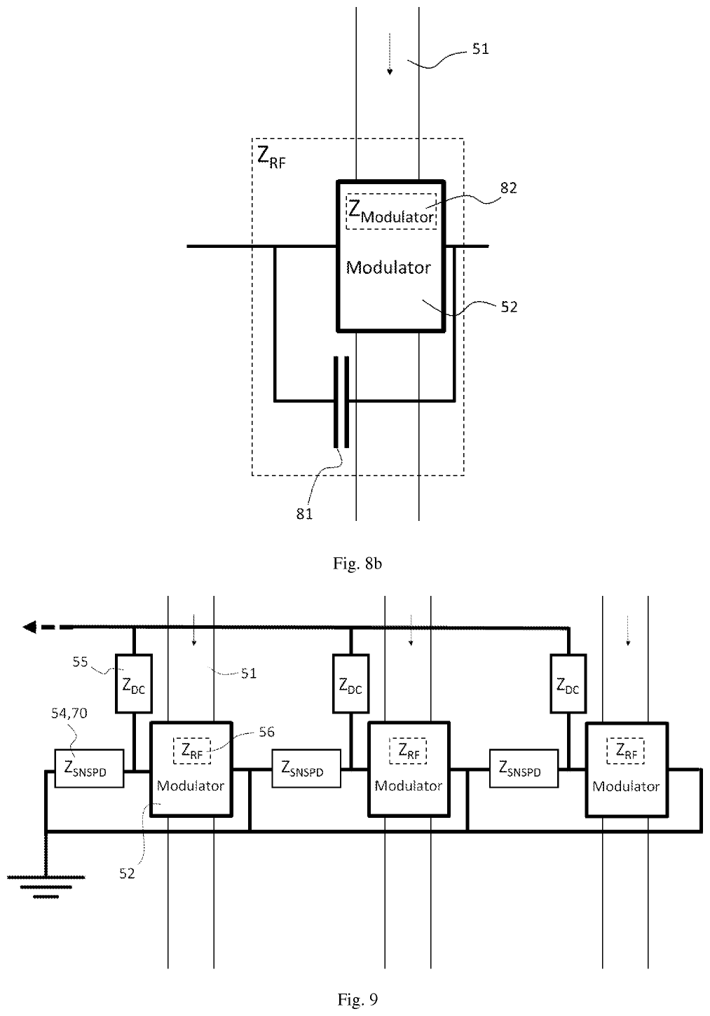

As illustrated in FIGS. 8a and 8b, if the modulator 52 is not intrinsically capacitive, an additional capacitor 81 can be coupled to the modulator 52. If the modulator has low resistive impedance Z_{Modulator} 80, the capacitor 81 is connected in series. If the modulator has high resistive impedance 82, the capacitor 81 can be connected in parallel. Another way to fulfil the condition Z_{RF}<Z_{DC} at high frequency without having a capacitive Z_{RF} would be to have an inductive Z_{DC}. In this case Z_{DC} would be low at low frequency and high at high frequency.

FIG. 9 further illustrates an example electrical circuit for a plurality of modulators 52. A substantial advantage of above-illustrated embodiments is that electrical cables are no longer required to readout the photon counts. Even if there are multiple detectors on the chip, all detectors can be biased with only one electric cable.

With reference to the embodiments illustrated in connection with FIGS. 2a and 2b, after the modulated light is re-multiplexed on the chip 1, guided through the fiber 25, 28 out of the cryostat 22 and de-multiplexed, the optical modulation needs to be detected and converted into electrical signals by detectors 27. The modulators 4, 35, 52 on the chip may be phase shifters, the phase shifts indicating the detection of photons on each channel that can be detected with an interferometer.

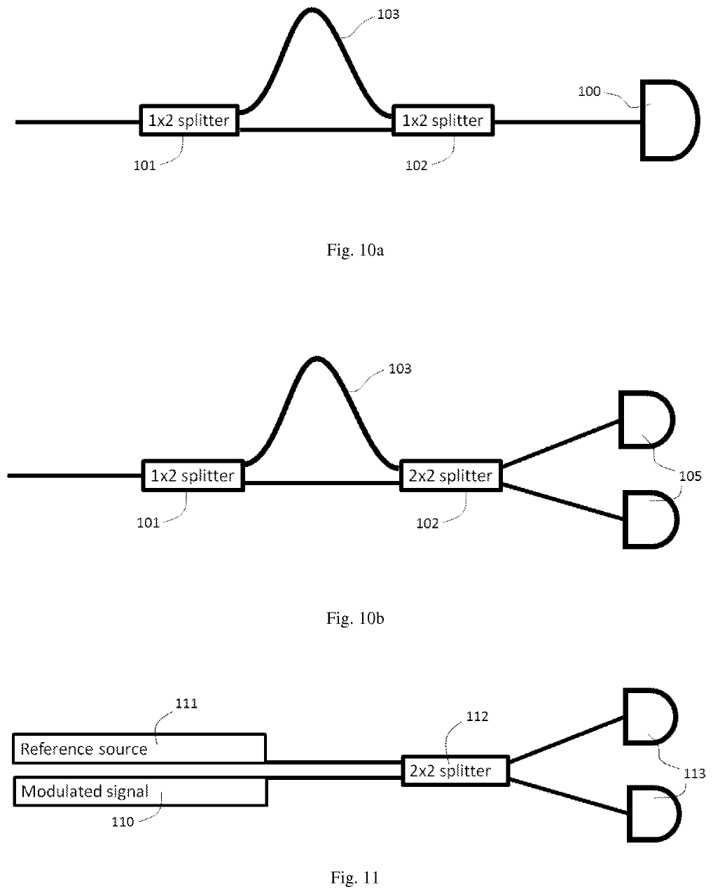

With reference to FIGS. 10a and 10b, a self-referenced interferometer 100, 105 may be used to compare the phase of an input signal via splitters 101, 102 with its own phase a short time before with the help of a delay 103. The intensity measured after recombining the signal and its delayed version will vary with varying phase.

As illustrated in FIG. 11, an external reference 111 may be applied for measuring the phase shifts in the modulated signal 110. The reference 111 may be obtained by tapping into the unmodulated source signal. In another embodiment amplitude modulation is applied, however, sensitivity may be lower.

In some embodiments time division multiplexing (TDM) is used to readout the multiple detectors 3 with a single fibre input and output. Thus, a single wavelength may be injected in the fibre output 5. A photonic switch may be provided on the chip 1 for directing the light sequentially in one waveguide after another, replacing the AWGs 32 and 39.

In an embodiment, a combination of TDM and WDM is used to provide the modulated signal to the fibre output 5. Thus, each wavelength of the readout optical signal may be separated as illustrated in FIGS. 3 and 4, and a switch may be used to split the light into even more waveguides. The waveguides, AWGs, switches and modulators can be fabricated with Complementary metal oxide semiconductor (CMOS) technology. Then a thin film of superconducting material, such as Niobium Nitride NbN, amorphous Tungsten Silicide WSi, or amorphous Molybdenum Silicide MoSi, can be deposited. Finally the nanowires can be etched into the superconducting film. It is to be noted order of these manufacturing steps may differ, as long as the film is deposited before etching. As another example, III-V materials technology may be applied instead of CMOS.

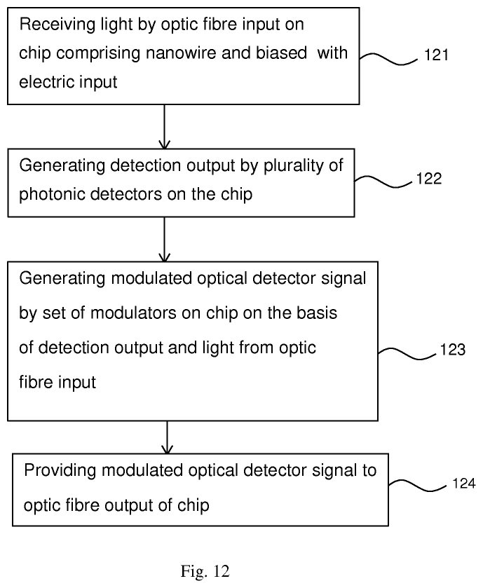

FIG. 12 is a flow graph of a method. The phases of the illustrated method may be performed on a chip for reading multiple photonic detectors, such as the chip 1 according to at least some of the embodiments illustrated above. Incoming light is received 121 by an optic fibre input on a chip comprising a nanowire and biased with an electric input. Detection output is generated 122 by a plurality of photonic detectors on the chip. A set of the modulators is connected to the optic fibre input and to the photonic detectors, such as the detectors 3 directly connected to each respective modulator 4 to provide the detection output signal or pulses to the modulator 4. A modulated optical detector signal is generated 123 by a set of modulators on the chip on the basis of the detection output from the photonic detectors and the light from the optic fibre. The modulated optical detector signal is provided 124 to an optic fibre output of the chip.

It will be appreciated that some or all of the embodiments illustrated above in connection with FIGS. 1 to 11 may be applied in addition to the method illustrated in FIG. 12. For example, the wavelength-modulation related features illustrated in FIGS. 2a to 4 may be applied, whereby the method may further comprise the demultiplexing (32), the multiplexing (39) and the further demultiplexing (26) actions. Furthermore, a chip, an apparatus or a device may be provided which may be configured to perform or comprise means for carrying out the phases of FIG. 12 and its further embodiments.

The chip 1 and the apparatus system capable of supporting at least some embodiments illustrated above may be applied in a wide variety of electronic devices. Such electronic device applying photonic detection may be an information processing, measuring, and/or communication device, for example. The device may include one or more chips 1 in accordance with at least some of the embodiments illustrated above. For example, the chip 1 and/or the device 130 may be applicable or configured for quantum information processing, such as quantum cryptography and key distribution (QKD), optical quantum computing, and quantum simulation, characterization of quantum emitters, optical communications e.g. for space-to-ground communications, optoelectronics, integrated circuit testing, fibre sensing and time-of-flight ranging. Some other example application areas include biotechnology applications, such as bio-luminescence, single molecule detection and DNA sequencing, astrophysics, nuclear particle detection, spectroscopy, meteorology, such as remote sensing, environmental monitoring and lidar, metrology, such as quantum standards, primary radiometric scales and quantum enhanced measurements, and medical physics, such as medical imaging, radioactivity monitoring, and clinical tomography.

The electronic device may further comprise various other units, such as at least one single- or multi-core processor with at least one processing core and at least one memory including computer program code. The at least one memory and the computer program code may be configured to, with the at least one processing core cause the device to perform certain actions are defined in the computer program. The device may also comprise a transmitter, a receiver, and/or a user interface, for example.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present invention find industrial application in systems applying optical detection, such as quantum information systems.

### ACRONYMS LIST

ASIC Application-specific integrated circuit
CMOS Complementary metal oxide semiconductor
DWDM Dense wavelength division multiplexing
DC Direct current
FPGA Field-programmable gate array
GSM Global system for mobile communication
LTE Long term evolution
NFC Near-field communication
QKD Quantum key distribution
SNSPD Superconducting nanowire single photon detectors
TDM Time division multiplexing
UI User interface
WCDMA Wideband code division multiple access,
WiMAX Worldwide interoperability for microwave access
WLAN Wireless local area network CITATION LIST

### Non-Patent Literature

“Ultra-Compact Silicon Photonic 512×512 25 GHx Arrayed Waveguide Grating Router”, S Cheung et al, IEEE Journal of Selected Topics in Quantum Electonics, Col. 20, July/August 2014; http://ieeexplore.ieee.org/stamp/stamp.jsp?arnumber=6691912
“Silicon Photonic Modulator Based on a MOS-Capacitor and a CMOS Driver”, M. Webster et al, 19-22 Oct. 2014, ISSN 1550-8781, DOI 10.1109/CSICS.2014.6978577; http://ieeexplore.ieee.org/stamp/stamp.jsp?arnumber=6978577

1-22. (canceled)

23. An apparatus comprising:
an optic fibre input;
a plurality of photonic detectors comprising a nanowire and biased with an electric input;
a set of modulators connected to the optic fibre input, each of the modulators being connected to one of the photonic detectors for forming a modulated optical detector signal; and
an optic fibre output for the modulated optical detector signal,
wherein the optic fibre input, the photonic detectors, the set of modulators, and the optic fibre output are formed on a single chip.

24. The apparatus according to claim 23, wherein the chip further comprises a first demultiplexer connected to the set of modulators for providing a selected wavelength of light from a multi-wavelength light source to each modulator.

25. The apparatus according to claim 23, wherein the chip further comprises a multiplexer for combining signals from each of the modulators into a single optic fibre connectable to the chip.

26. The apparatus according to claim 25, wherein the apparatus further comprises or is connectable to
a second demultiplexer for demultiplexing the modulated optical detector signal in the single optic fibre, and
a set of interferometric phase detectors connected to the second multiplexer, arranged to detect modulation at the demultiplexed optical detector signal.

27. The apparatus according to claim 26, wherein the multiplexer and the second demultiplexer are connectable to the same single optic fibre for both the optic fibre input and the optic fibre output, and the single optic fibre is connectable to a circulator for separating the input and the output.

28. The apparatus according to claim 23, wherein the biasing of the plurality of photonic detectors is arranged with a single electric wire.

29. The apparatus according to claim 23, wherein the chip is cryogenically refrigerated and the photonic detectors are superconducting nanowire single photon detectors directly connected to respective modulators.

30. The apparatus according to claim 29, wherein each of the photonic detectors is a waveguide-coupled detector.

31. The apparatus according to claim 23, wherein each of the photonic detectors is a vertically-coupled detector, wherein the light is arranged directly from an optic fibre or from an optical window in a cryostat.

32. The apparatus according to claim 23, wherein each of the modulators is capacitive or the chip comprises a capacitor connected in parallel or in series to the modulator.

33. The apparatus according to claim 23, wherein the apparatus is an information processing or a communications device comprising at least one processing core, and at least one memory including computer program code, configured to, with the at least one processing core, cause the apparatus to at least perform any of claims 1-10.

34. A method, comprising:
receiving light by an optic fibre input on a chip;
generating detection output by a plurality of photonic detectors on the chip comprising a nanowire and biased with an electric input;
generating a modulated optical detector signal by a set of modulators on the chip connected to the photonic detectors on the basis of the detection output from the photonic detectors and the received light; and
providing the modulated optical detector signal to an optic fibre output of the chip.

35. The method according to claim 34, further providing, by a first demultiplexer on the chip, a selected wavelength of light from a multi-wavelength light source to each modulator.

36. The method according to claim 34, further combining, by a multiplexer on the chip, signals from each of the modulators into a single optic fibre connectable to the chip being cryogenically refrigerated.

37. The method according to claim 36, further demultiplexing, by a second demultiplexer, the modulated optical detector signal in the single optic fibre, and
detecting, by a set of interferometric phase detectors connected to the second multiplexer, modulation at the demultiplexed optical detector signal.

38. The method according to claim 37, wherein the multiplexer and the second demultiplexer are connected to the same single optic fibre for both the optic fibre input and the optic fibre output, and the single optic fibre is connected to a circulator for separating the input and the output.

39. The method according to claim 34, wherein the biasing of the plurality of photonic detectors is arranged with a single electric wire.

40. The method according to claim 34, wherein the photonic detectors are superconducting nanowire single photon detectors directly connected to respective modulators.

41. The method according to claim 40, wherein the photonic detectors are waveguide-coupled detectors, the photons being injected in the waveguide from the optic fibre by a grating coupler or a taper.

42. The method according to claim 34, wherein each of the photonic detectors is a vertically-coupled detector, wherein the light is arranged directly from the optic fibre or from an optical window in a cryostat.
